(19) United States
(12) Patent Application Publication
(10) Pub. No.: US 2025/0293204 A1
(43) Pub. Date: Sep. 18, 2025

(54) INTEGRATED CIRCUIT DEVICE INCLUDING A MULTI-CHIP PACKAGE

(71) Applicant: QUALCOMM Incorporated, San Diego, CA (US)

(72) Inventors: Je-Hsiung LAN, San Diego, CA (US); Jonghae KIM, San Diego, CA (US); Ranadeep DUTTA, Del Mar, CA (US)

(21) Appl. No.: 18/605,749

(22) Filed: Mar. 14, 2024

(51) Int. Cl. H01L 25/065; H01L 23/00; H01L 23/552; H01L 23/66; H01L 25/00

(52) U.S. Cl. CPC H01L 25/0652; H01L 23/552; H01L 23/66; H01L 24/16; H01L 24/81; H01L 25/50; H01L 2223/6605; H01L 2223/6644; H01L 2224/16148; H01L 2224/16227; H01L 2224/81005; H01L 2924/14215; H01L 2924/182

(57) ABSTRACT

A multi-chip package includes a first chiplet including power amplifier (PA) circuitry. The multi-chip package also includes a second chiplet including low-noise amplifier (LNA) circuitry. The multi-chip package further includes an electromagnetic interference (EMI) shield between the first chiplet and the second chiplet. The multi-chip package also includes mold compound at least partially encapsulating the first chiplet, the second chiplet, and the EMI shield.

### FIELD

Various features relate to integrated circuit devices.

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power and signal routing issues when multiple dies are arranged side-by-side within the small form factor.

### SUMMARY

Various features relate to integrated circuit devices.

One example provides a multi-chip package that includes a first chiplet including power amplifier (PA) circuitry. The multi-chip package also includes a second chiplet including low-noise amplifier (LNA) circuitry. The multi-chip package further includes an electromagnetic interference (EMI) shield between the first chiplet and the second chiplet. The multi-chip package also includes mold compound at least partially encapsulating the first chiplet, the second chiplet, and the EMI shield.

Another example provides a packaged integrated circuit device that includes a first chiplet including PA circuitry. The packaged integrated circuit device also includes a second chiplet including LNA circuitry. The packaged integrated circuit device further includes a third chiplet that includes radio frequency (RF) circuitry, first contacts on a first surface, second contacts on a second surface, and conductors electrically connecting one or more of the first contacts to one or more of the second contacts. A first subset of the first contacts are electrically connected to the first chiplet and a second subset of the first contacts are electrically connected to the second chiplet. The second contacts are configured to electrically connect to off package components.

Another example provides a stacked integrated circuit device that includes a multi-chip package stacked with a RF interposer chiplet. The multi-chip package includes a first chiplet including first circuitry, a second chiplet including second circuitry, and mold compound at least partially encapsulating the first chiplet and the second chiplet. The RF interposer chiplet includes RF circuitry. The RF interposer chiplet also includes first contacts, on a first surface, electrically connected to the first chiplet and the second chiplet of the multi-chip package.

Another example provides a method of fabrication. The method includes attaching a first chiplet including PA circuitry to a carrier substrate. The method also includes attaching a second chiplet including LNA circuitry to the carrier substrate. The method further includes forming an EMI shield between the first chiplet and the second chiplet. The method also includes at least partially encapsulating the first chiplet, the second chiplet, and the EMI shield in a mold compound to form a multi-chip package.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary IC device that includes an embedded multi-chip package.

FIG. 2 illustrates examples of an EMI shield of the embedded multi-chip package of FIG. 1.

FIG. 3 illustrates a top view of a reconstituted wafer and a cross sectional profile view of an exemplary IC device that includes an embedded multi-chip package obtained from the reconstituted wafer.

FIG. 4 illustrates a cross sectional profile view of the reconstituted wafer of FIG. 3.

FIG. 5 illustrates a cross sectional profile view of an exemplary IC device that includes an embedded multi-chip package.

FIG. 6 (which extends across multiple pages) illustrates an exemplary sequence for fabricating an exemplary IC device that includes an embedded multi-chip package.

FIG. 7 (which extends across multiple pages) illustrates an exemplary sequence for fabricating another exemplary IC device that includes an embedded multi-chip package.

FIG. 8 illustrates an exemplary flow diagram of a method of fabricating an exemplary IC device that includes an embedded multi-chip package.

FIG. 9 illustrates an exemplary flow diagram of another method of fabricating an exemplary IC device that includes an embedded multi-chip package.

FIG. 10 illustrates various electronic devices that may integrate an embedded multi-chip package and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of mobile application devices. These mobile applications, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. Unfortunately, stacked die schemes can involve high power density targets, which impose significant power distribution inefficiencies. Various aspects of the present disclosure provide a stacked IC device arranged to provide improved integration of a capacitor with a power distribution network (PDN), resulting in improved PDN performance.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Aspects of the present disclosure are directed to an IC device that includes an multi-chip package (also referred to herein as an “embedded multi-chip package”). In this context, the term “embedded multi-chip package” refers to an article that includes multiple chips or chiplets encased (fully or partially) in a structural matrix (e.g., mold compound) and having external contacts that enable electrical connections to each of the multiple chips or chiplets such that the multiple chips or chiplets can be used together in manufacturing processes as a single component. In some aspects of the present disclosure, the embedded multi-chip package includes a first chiplet including first circuitry (e.g., power amplifier (PA) circuitry) and a second chiplet including second circuitry (e.g., low-noise amplifier (LNA) circuitry). The embedded multi-chip package also includes an electromagnetic interference (EMI) shield between the first chiplet and the second chiplet. In some aspects of the present disclosure, the embedded multi-chip package is stacked with a radio frequency (RF) interposer chiplet. The RF interposer chiplet includes RF circuitry, such as transceiver (TRX) circuitry. The RF interposer chiplet includes first contacts on a first surface, second contacts on a second surface, and conductors (e.g., through silicon vias (TSVs)) electrically connecting one or more of the first contacts to one or more of the second contacts. A first subset of the first contacts are electrically connected to the first chiplet, and a second subset of the first contacts are electrically connected to the second chiplet. The second contacts are configured to electrically connect to off package components.

### Exemplary IC Device Including Embedded Multi-Chip Package

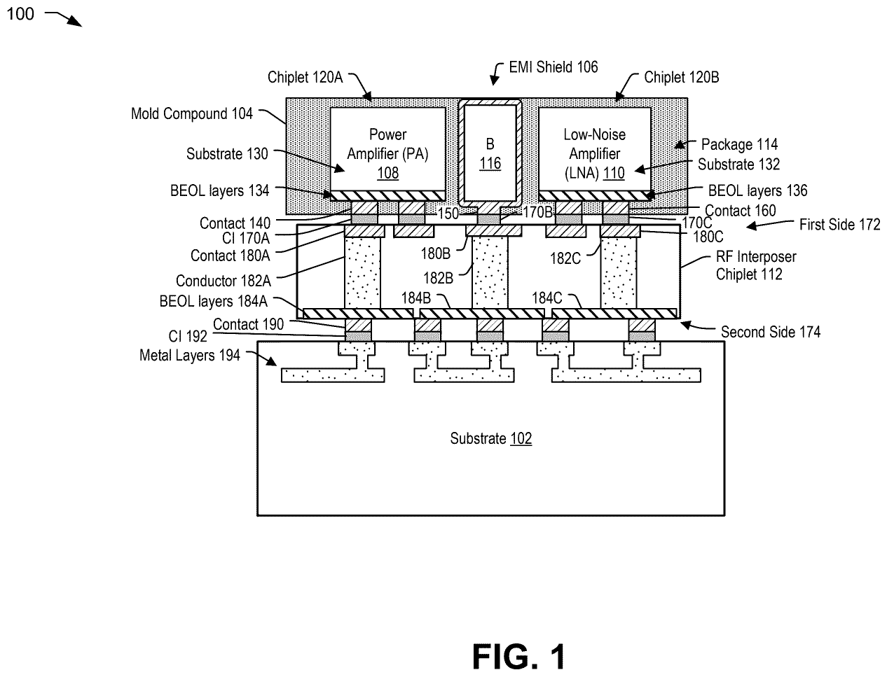

FIG. 1 illustrates a cross sectional profile view of an exemplary device 100 (e.g., a stacked IC device) that includes a package 114 (e.g., an embedded multi-chip package) stacked with a RF interposer chiplet 112. The package 114 includes a chiplet 120A and a chiplet 120B. The package 114 also includes an EMI shield 106 between the chiplet 120A and the chiplet 120B. The EMI shield 106 is configured to reduce (e.g., block) electromagnetic interference between the chiplet 120A and the chiplet 120B. In a particular aspect, the EMI shield 106 has a magnetic field strength (B) 116.

Each chiplet can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a FEOL process may be used to fabricate the integrated circuitry in and/or over the semiconductor substrate.

The chiplet 120A includes active circuitry formed in or on a substrate 130, and the chiplet 120B includes active circuitry formed in or on a substrate 132. In the example of the device 100 of FIG. 1, the chiplet 120A includes power amplifier (PA) circuitry 108, and the chiplet 120B includes low-noise amplifier (LNA) circuitry 110. Optionally, in some aspects, the substrate 130 is of a first substrate material that is distinct from a second substrate material of the substrate 132. For example, the first substrate material includes at least one of gallium arsenide (GaAs) or indium phosphide (InP), and the second substrate material includes silicon (Si). It should be understood that the chiplet 120A including the PA circuitry 108, and the chiplet 120B including the LNA circuitry 110 is provided as an illustrative example, in other examples the chiplet 120A, the chiplet 120B, or both, can include other types of active components, passive components, or both.

The chiplet 120A includes BEOL layers 134 on a first side of the chiplet 120A to electrically connect one or more contacts 140 on the first side to the active circuitry (e.g., the PA circuitry 108) of the chiplet 120A. In some aspects, the BEOL layers 134 can include one or more active layers, one or more passive layers, or a combination thereof. The chiplet 120B includes BEOL layers 136 on a first side of the chiplet 120B to electrically connect one or more contacts 160 on the first side to the active circuitry (e.g., the LNA circuitry 110) of the chiplet 120B. In some aspects, the BEOL layers 136 can include one or more active layers, one or more passive layers, or a combination thereof. The EMI shield 106 includes one or more contacts 150 on a first side of the EMI shield 106. The chiplet 120A, the chiplet 120B, and the EMI shield 106 are at least partially encapsulated in a mold compound 104. In some implementations, the RF interposer chiplet 112 may be at least partially encapsulated in a mold compound.

The RF interposer chiplet 112 includes contacts 180, conductors 182, and BEOL layers 184. In some aspects, the BEOL layers 184 can include one or more active layers, one or more passive layers, or a combination thereof. In a particular aspect, a conductor 182 corresponds to a through-silicon via (TSV). The conductors 182 electrically connect one or more of the contacts 180 on a first side 172 (e.g., a first surface) of the RF interposer chiplet 112 to one or more BEOL layers 184 on a second side 174 (e.g., a second surface) of the RF interposer chiplet 112. For example, a contact 180A is electrically connected via a conductor 182A (e.g., a through silicon via (TSV)) to BEOL layers 184A. As another example, a contact 180B is electrically connected via a conductor 182B (e.g., a TSV) to BEOL layers 184B. As a further example, a contact 180C is electrically connected via a conductor 182C (e.g., a TSV) to BEOL layers 184C. It should be understood that BEOL layers are provided as an illustrative example of a type of contacts of the RF interposer chiplet 112, in other examples the RF interposer chiplet 112 can include another type of contacts on the second side 174 that are electrically connected to the conductors 182.

The RF interposer chiplet 112 also includes RF circuitry (not shown). In some examples, the RF interposer chiplet 112 includes a transmitter chiplet that includes transmitter circuitry. In some examples, the RF interposer chiplet 112 includes a receiver chiplet that includes receiver circuitry. In some examples, the RF interposer chiplet 112 includes a transceiver chiplet that includes transceiver circuitry, such as transmitter circuitry and receiver circuitry. In some aspects, the RF interposer chiplet 112 includes one or more passive devices, such as one or more de-coupling capacitors or inductors.

In the device 100 of FIG. 1, the package 114 is coupled on a first side of the package 114 to the first side 172 of the RF interposer chiplet 112. For example, a first subset of the contacts 180 are electrically connected to one or more of the contacts 140 of the chiplet 120A. To illustrate, the contact 180A is electrically connected via a conductive interconnect 170A to a contact 140 of the chiplet 120A. As another example, a second subset of the contacts 180 are electrically connected to one or more of the contacts 160 of the chiplet 120B. To illustrate, the contact 180C is electrically connected via a conductive interconnect 170C to a contact 160 of the chiplet 120B. In an example, the RF interposer chiplet 112 is electrically connected to the EMI shield 106. To illustrate, the contact 180B is electrically connected to the contact 150 of the EMI shield 106.

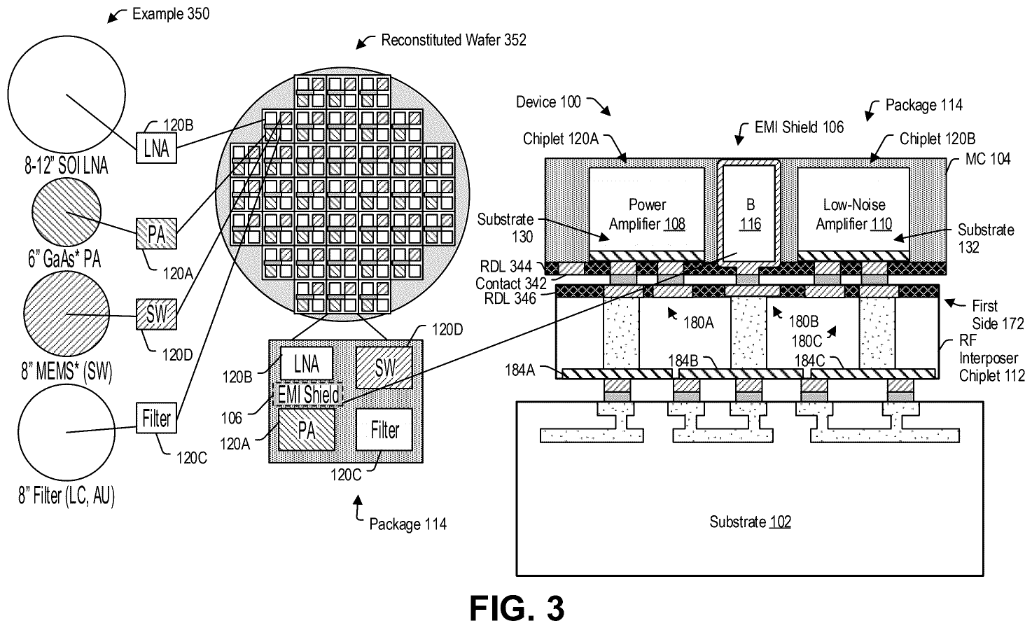

Optionally, in some aspects, one or more of the first subset of contacts 180 electrically connect active circuitry (e.g., the PA circuitry 108) of the chiplet 120A to active circuitry (e.g., transmitter circuitry of a transmitter chiplet) of the RF interposer chiplet 112. Optionally, in some aspects, one or more of the second subset of contacts 180 electrically connect active circuitry (e.g., the LNA circuitry 110) of the chiplet 120B to active circuitry (e.g., receiver circuitry of a receiver chiplet) of the RF interposer chiplet 112. In some aspects, the RF interposer chiplet 112 operates as an interposer enabling communication between the chiplets 120, as further described with reference to FIG. 3.

The RF interposer chiplet 112 is electrically connected to a substrate 102. For example, the BEOL layers 184 on the second side 174 of the RF interposer chiplet 112 are electrically connected via one or more contacts 190 and one or more conductive interconnects 192 to metal layers 194 of the substrate 102. In some aspects, one or more of the BEOL layers 184 of the RF interposer chiplet 112 are configured to electrically connect to off-package components.

The RF interposer chiplet 112 enables communication between the BEOL layers 134, 136 of the chiplets 120 and the substrate 102. In some aspects, the chiplet 120A (e.g., the PA circuitry 108) is electrically connected to the substrate 102. For example, the device 100 includes a conductive path from the chiplet 120A (e.g., the PA circuitry 108) through the BEOL layers 134, a contact 140, the conductive interconnect 170A, the contact 180A, the conductor 182A, the BEOL layers 184A, the contact 190, and the conductive interconnect 192 to the metal layers 194 of the substrate 102.

In some aspects, the chiplet 120B (e.g., the LNA circuitry 110) is electrically connected to the substrate 102. For example, the device 100 includes a conductive path from the chiplet 120B (e.g., the LNA circuitry 110) through the BEOL layers 136, a contact 160, the conductive interconnect 170C, the contact 180C, the conductor 182C, the BEOL layers 184C, a contact, and a conductive interconnect to the metal layers 194 of the substrate 102.

Any of the conductive interconnects and contacts described herein can include, for example, microbumps, conductive pillars, conductive pads (e.g., for pad-to-pad bonding), or other similar chiplet-to-chiplet interconnect contacts used for three-dimensional (3D) chiplet stacking. In some implementations, the chiplet 120A, the chiplet 120B, and the RF interposer chiplet 112 are designed to operate in conjunction with each other. To illustrate, in some implementations, the active circuitry of the chiplet 120A includes one or more first functional circuit blocks, the active circuitry of the chiplet 120B includes one or more second functional circuit blocks, and the active circuitry of the RF interposer chiplet 112 includes one or more third functional circuit blocks, where the one or more third functional circuit blocks are operationally dependent on the one or more first functional circuit blocks, the one or more second functional circuit blocks, or a combination thereof. The cross-sectional profile view illustrated in FIG. 1 shows an example of the package 114 including two chiplets. In other views or examples, the package 114 can include more than two chiplets, such as a filter chiplet, a switch chiplet, or both, as further described with reference to FIG. 3.

Forming the device 100 using chiplets arranged and interconnected as a 3D stacked IC can provide various benefits as compared to providing the same functional circuitry in one monolithic chip. For example, each chiplet is smaller than a monolithic die including all of the same functional circuit blocks would be. Since yield loss in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one chiplet of a chiplet-based integrated device (e.g., the chiplet 120A of the device 100) can include components (e.g., interconnects, transistors, etc.) that have a first minimum size, and another chiplet of the chiplet-based integrated device (e.g., the chiplet 120B of the device 100) can include components (e.g., interconnects, transistors, etc.) that have a second minimum size, where the second minimum size is greater than the first minimum size. In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. In contrast, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form an IC (e.g., the device 100), resulting in overall savings. Still further, in some cases, as technology improves, the design of a chiplet can be changed. Chiplet stacking allows such new chiplet designs to be integrated with older chiplet designs to form stacked IC devices, which improves manufacturing flexibility and reduces design costs.

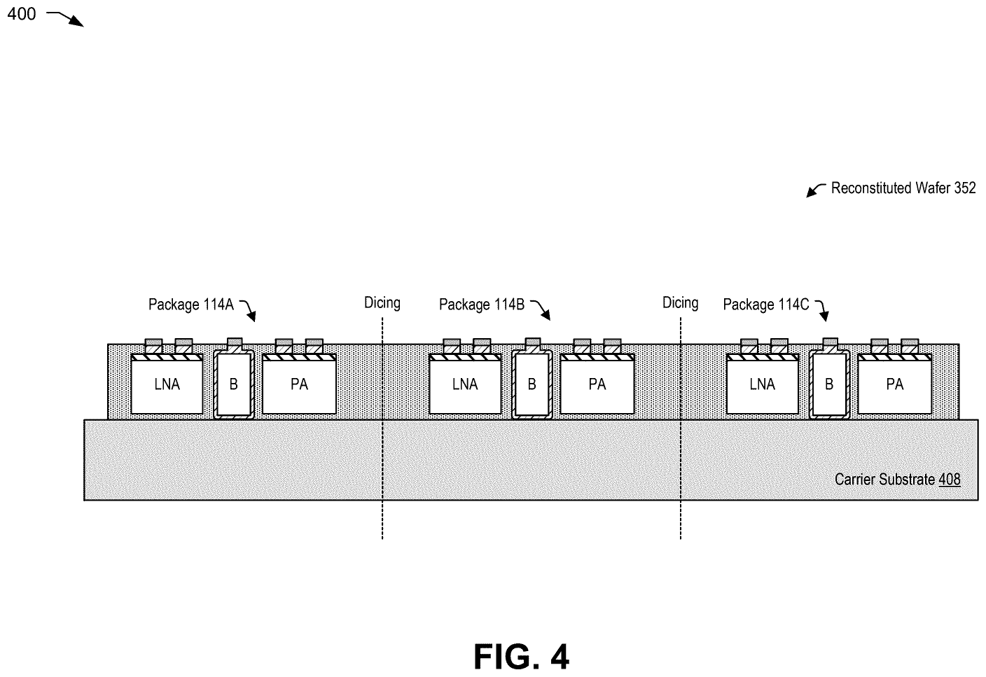

In a particular aspect, multiple packages 114 can be formed on a reconstituted wafer, as further described with reference to FIG. 3. For example, the reconstituted wafer can be diced to obtain a package 114 that can be bonded with the RF interposer chiplet 112, as further described with reference to FIGS. 4, 6, and 7. The device 100 can thus be formed with a single bonding process to stack the components (e.g., the chiplet 120A, the EMI shield 106, and the chiplet 120B) of the package 114 on the RF interposer chiplet 112, as compared to a multi-step process of individually bonding each of the components to the RF interposer chiplet 112.

While one benefit of using stacked IC devices (such as the device 100) is reduced footprint of such devices as compared to comparable monolithic IC devices, this reduced footprint can give rise to challenges with electromagnetic interference. A technical advantage of having the EMI shield 106 between the chiplet 120A and the chiplet 120B is that the chiplet 120A and the chiplet 120B can be positioned as close as possible with reduced (e.g., none) electromagnetic interference, leading to improved power-performance-area-cost (PPAC) characteristics.

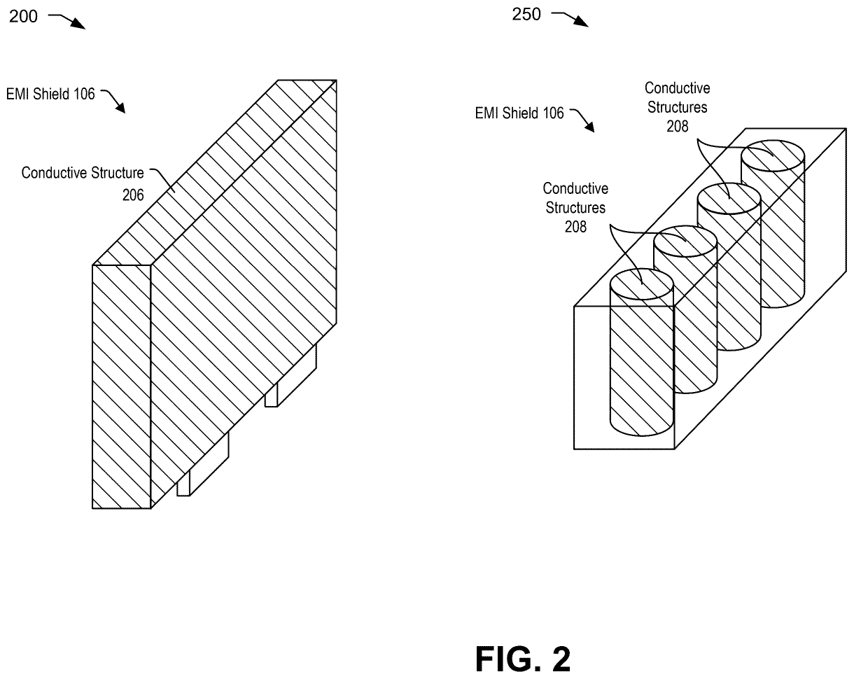

FIG. 2 illustrates an example 200 and an example 250 of an EMI shield 106 of the package 114 of FIG. 1. In the example 200, the EMI shield 106 is a single conductive structure 206. To illustrate, the single conductive structure 206 can include a wall-like structure with a metallic (e.g., copper) coating.

In the example 250, the EMI shield 106 includes a plurality of conductive structures 208. To illustrate, the EMI shield 106 can include an array of conductive structures 208. In a particular implementation, a conductive structure 208 can include a metallic (e.g., copper) pillar.

FIG. 3 illustrates a top view of a reconstituted wafer 352 and a cross sectional profile view of the device 100 (e.g., an exemplary IC device) that includes the package 114 (e.g., a multi-chip package) obtained from the reconstituted wafer 352.

In FIG. 3, the package 114 is illustrated as including one or more redistribution layers (RDL) 344 coupled to the mold compound 104 and electrically connected to the chiplet 120A, the EMI shield 106, and the chiplet 102B. For example, the RDL 344 can include the one or more contacts 140 electrically connected to the BEOL layers 134 of the chiplet 120A, the one or more contacts 150 electrically connected to the EMI shield 106, and the one or more contacts 160 electrically connected to the BEOL layers 136 of the chiplet 120B. In some aspects, the RDL 344 can include one or more additional contacts, such as a representative contact 342. It should be understood that any embodiments of the package 114 described herein can optionally include the RDL 344 even if not illustrated.

In FIG. 3, the RF interposer chiplet 112 is illustrated as including RDL 346 on the first side 172 of the RF interposer chiplet 112, and configured to be electrically connected to the chiplet 120A, the EMI shield 106, the chiplet 120B, and the BEOL layers 184. For example, the RDL 346 includes one or more contacts 180A that are configured to be electrically connected via one or more conductive interconnects 170A to one or more contacts 140 of the RDL 344 that are electrically connected to the BEOL layers 134 of the chiplet 120A. As another example, the RDL 346 includes one or more contacts 180B that are configured to be electrically connected via one or more conductive interconnects 170B to one or more contacts 150 of the RDL 344 that are electrically connected to the EMI shield 106. In yet another example, the RDL 346 includes one or more contacts 180C that are configured to be electrically connected via one or more conductive interconnects 170C to one or more contacts 160 of the RDL 344 that are electrically connected to the BEOL layers 136 of the chiplet 120B. In some aspects, one or more of the contacts 180 are electrically connected via conductors 182 (e.g., TSVs) to one or more of the BEOL layers 184. In some aspects, the RF interposer chiplet 112 operates as an interposer enabling communication between the chiplet 120A and the chiplet 120B through the RDL 346. The RF interposer chiplet 112 also enables communication between the chiplets 120 and the substrate 102. It should be understood that any embodiments of the RF interposer chiplet 112 described herein can optionally include the RDL 346 even if not illustrated.

A plurality of packages 114 are formed on the reconstituted wafer 352. Each package 114 includes a plurality of chiplets 120, such as a chiplet 120A, a chiplet 120B, a chiplet 120C, and a chiplet 120D, with at least a pair of the chiplets 120 separated by an EMI shield 106. It should be understood that a package 114 including four chiplets 120 and one EMI shield 106 is provided as an illustrative example, in other examples a package 114 can include fewer than four chiplets 120 or more than four chiplets 120 with one or more EMI shields 106.

In an example 350, the chiplet 120A corresponds to a power amplifier chiplet. In some implementations, active circuitry of the chiplet 120A includes at least one of gallium arsenide (GaAs), indium phosphide (InP), or gallium nitride (GaN) as semiconductor material. In a particular aspect, the power amplifier circuitry 108 of the chiplet 120A increases a power level of an input signal to drive an output load such as an antenna or a transmission line. In some implementations, the power amplifier circuitry 108 can operate across a wide range of frequencies. In some implementations, the power amplifier circuitry 108 can operate to amplify signals within a specific frequency band.

In the example 350, the chiplet 120B corresponds to a silicon-on-insulator (SOI) LNA chiplet. To illustrate, the LNA circuitry 110 is formed on a substrate 132 that includes a silicon layer separated from a silicon base by an insulator layer to reduce parasitic capacitance and leakage currents, improving performance of the LNA circuitry 110. In some implementations, the insulator layer includes silicon dioxide. In some aspects, the LNA circuitry 110 of the chiplet 120B is designed to amplify very weak signals while introducing as little noise as possible.

In the example 350, the chiplet 120C corresponds to a filter chiplet. For example, in some implementations, the chiplet 120C includes an inductor-capacitor (LC) filter. To illustrate, the LC filter is designed to filter out certain frequencies from a signal while letting other frequencies pass through. In some implementations, the LC filter includes gold (Au) connectors (e.g., contacts).

In the example 350, the chiplet 120D corresponds to a switch chiplet. In some implementations, the chiplet 120 includes a microelectromechanical systems (MEMS) switch. To illustrate, the switch chiplet operates to perform at least one of signal routing, impedance matching, tunability, beamforming, or antenna switching.

FIG. 4 illustrates a cross sectional profile view 400 of the reconstituted wafer 352. A plurality of packages 114, such as a package 114A, a package 114B, and a package 114C, are formed on a carrier substrate 408 of the reconstituted wafer 352.

It should be understood that three packages 114 formed on the carrier substrate 408 is provided as an illustrative example, in other examples fewer than three or more than three packages 114 can be formed on the carrier substrate 408. A dicing operation is performed on the reconstituted wafer 352 to separate the packages 114.

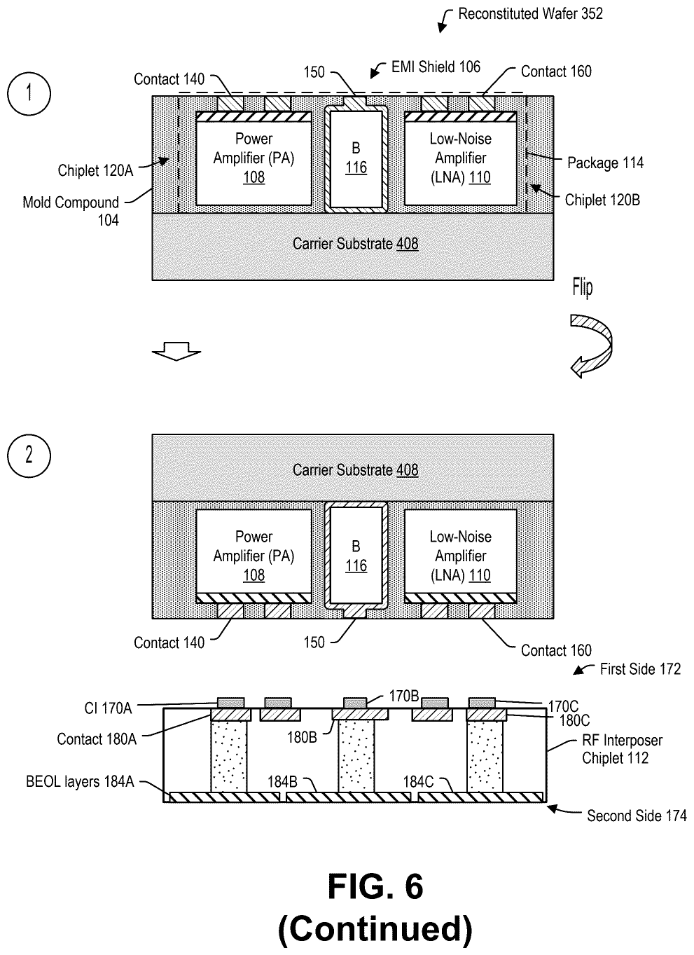

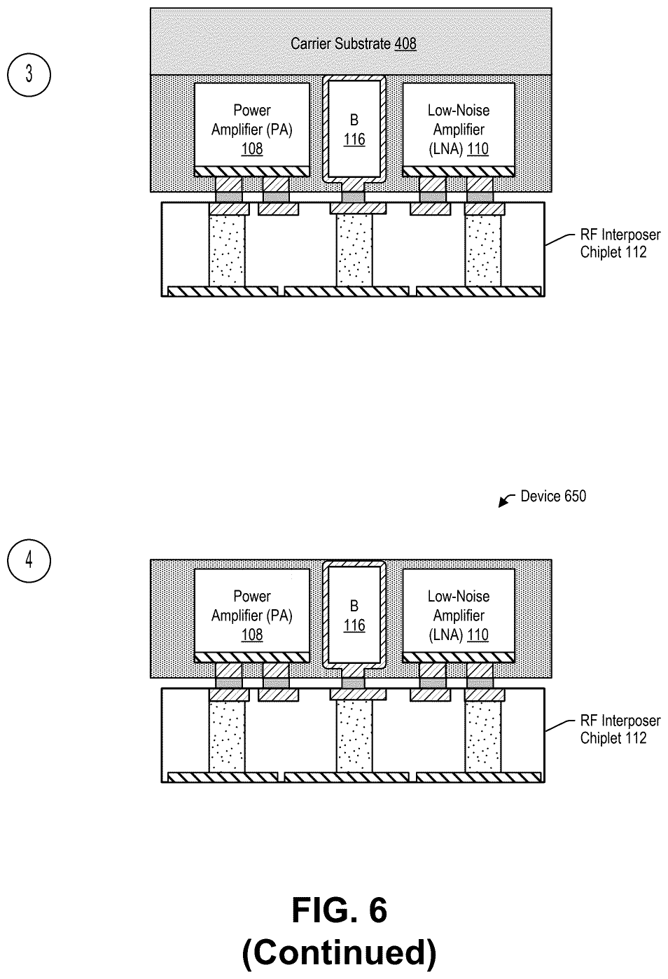

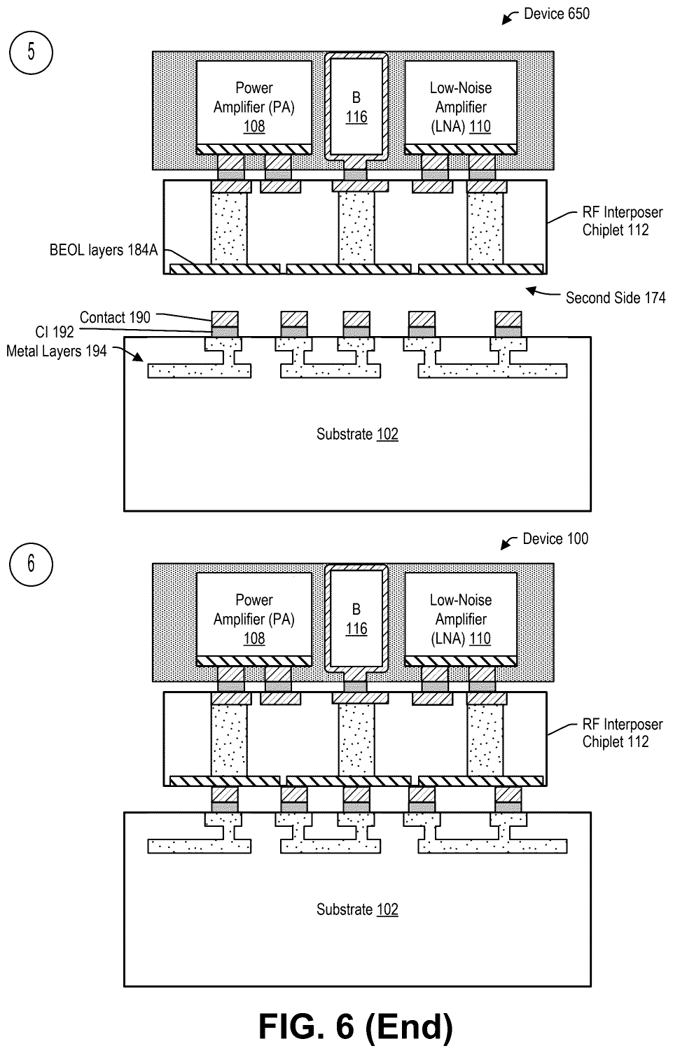

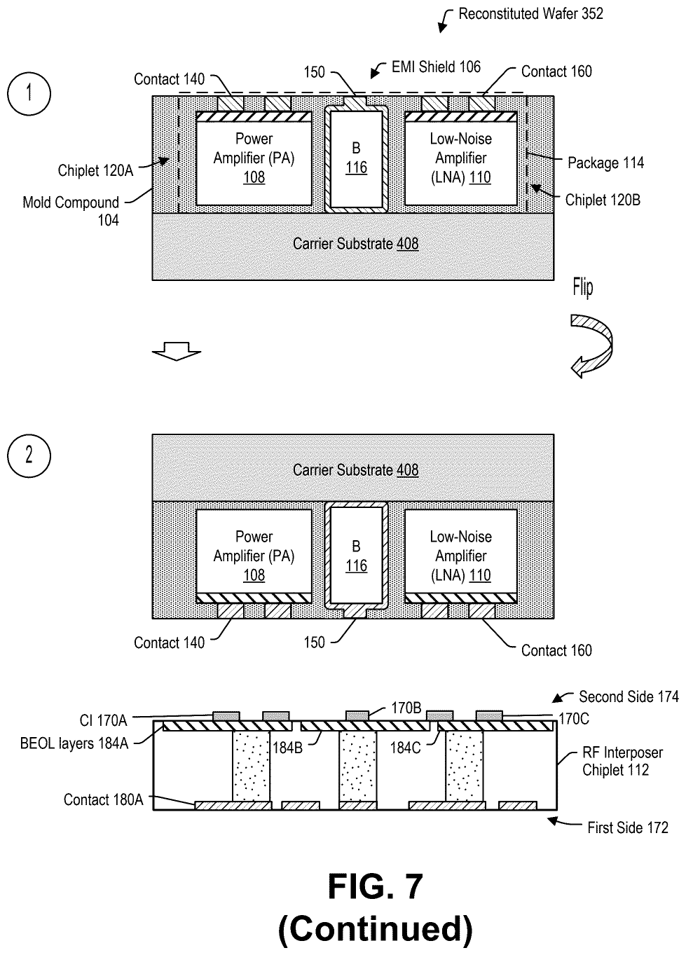

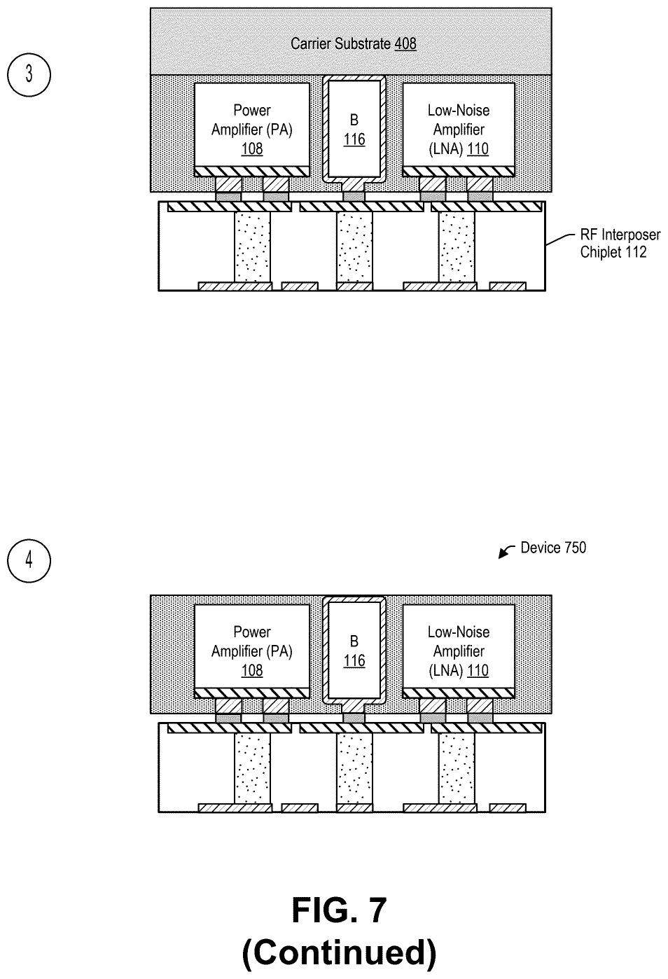

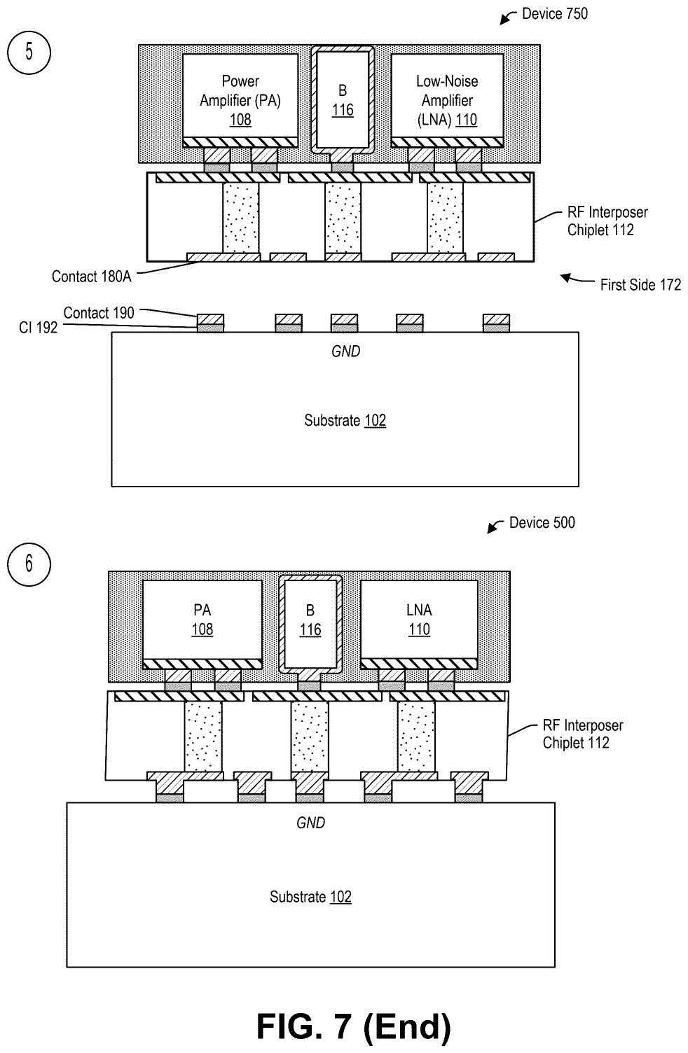

In some aspects, electrical testing of a package 114 is performed, e.g., using a chip probe. A package 114 that passes the electrical testing is bonded to the RF interposer chiplet 112, as further described with reference to FIGS. 6 and 7. A single bonding process can thus be used to stack the package 114 on the RF interposer chiplet 112. Attaching the package 114 after testing, instead of attaching individual components of the package 114, to the RF interposer chiplet 112 can result in yield improvements.

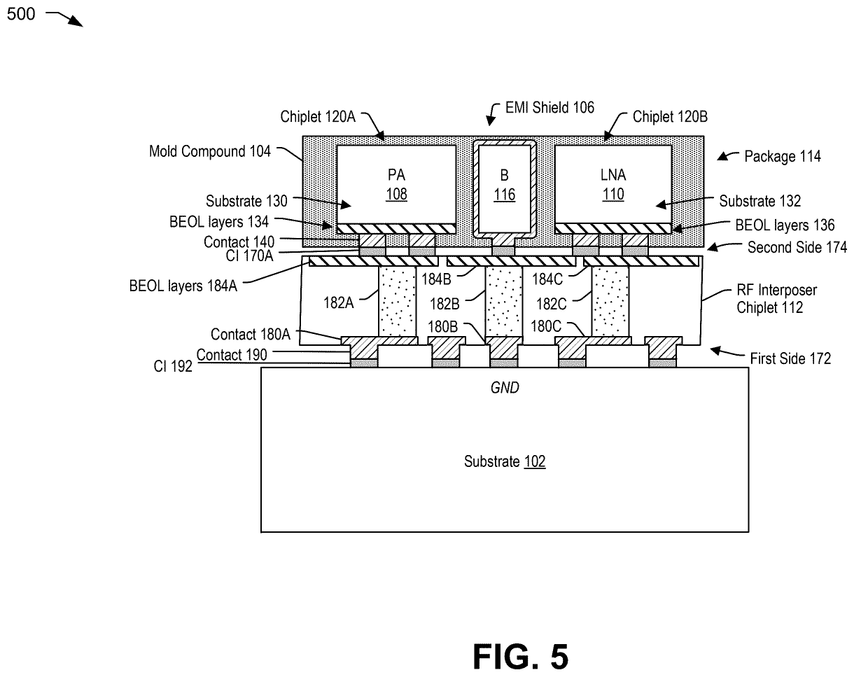

FIG. 5 illustrates a cross sectional profile view of a device 500 (e.g., an exemplary IC device) that includes a package 114 (e.g., a multi-chip package). In a particular aspect, an orientation of the RF interposer chiplet 112 is vertically flipped in the device 500 relative to the device 100. For example, the BEOL layers 184 on the second side 174 of the RF interposer chiplet 112 are electrically connected to the package 114, and the contacts 180 on the first side 172 of the RF interposer chiplet 112 are electrically connected to the substrate 102.

In an example, the BEOL layers 184A are electrically connected via the conductive interconnect 170 to the contact 140 on a first side of the chiplet 120A, and the contact 180A is electrically connected via the contact 190 and the conductive interconnect 192 to the substrate 102. In a particular aspect, the substrate 102 is used as ground and the metal layers 194 of FIG. 1 are absent from the substrate 102 of FIG. 5.

The stacked IC devices disclosed herein can be integrated with or included within a wide variety of other devices. For example, a device that includes one or more of the stacked IC devices disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the stacked IC device can operate as any of these components (or a combination of these components) that includes active circuitry.

### Exemplary Sequence for Fabricating an IC Device Including a Multi-Chip Package

In some implementations, fabricating an IC device including a multi-chip package (e.g., any of the devices 100 or 500) includes several processes. FIG. 6 (which is continued across multiple pages) illustrates an exemplary sequence for providing or fabricating a stacked IC device (e.g., the device 100) including a multi-chip package, as described with reference to FIG. 1.

It should be noted that the sequence of FIG. 6 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 6.

Stage 1 of FIG. 6 illustrates at least a portion of the reconstituted wafer 352. In a particular aspect, Stage 1 illustrates a state after dicing of the reconstituted wafer 352 into multiple portions. The portion of the reconstituted wafer 352 includes a package 114 formed on the carrier substrate 408. The package 114 includes an EMI shield 106 between a chiplet 120A and a chiplet 120B. The chiplet 120A, the EMI shield 106, and the chiplet 120B are at least partially encapsulated in the mold compound 104. In a particular aspect, temporary bonding is used to bond the chiplets 120 and the EMI shield 106 to the carrier substrate 408. In some embodiments, redistribution layers (e.g., the RDL 344 of FIG. 3) are formed on the reconstituted wafer, in which case the contacts 140, 150, 160 are contacts of the redistribution layers.

Stage 2 illustrates a state after the portion of the reconstituted wafer 352 is flipped vertically and positioned relative to a RF interposer chiplet 112. The RF interposer chiplet 112 includes the contacts 180 on or at the first side 172 of the RF interposer chiplet 112 with conductive interconnects 170 formed (e.g., deposited) on the contacts 180. In a particular aspect, the portion of the reconstituted wafer 352 is positioned to align the contacts 140, 150, and 160 of the package 114 with the conductive interconnects 170 on the RF interposer chiplet 112. For example, a contact 140 of the chiplet 120A is aligned with a conductive interconnect 170A, a contact 150 of the EMI shield 106 is aligned with a conductive interconnect 170B, a contact 160 of the chiplet 120B is aligned with a conductive interconnect 170.

Stage 3 illustrates a state after the contacts 140, 150, and 160 of the portion of the reconstituted wafer 352 are aligned and bonded with the conductive interconnects 170 on the RF interposer chiplet 112. In some implementations, hybrid bonding is used to bond the contacts 140, 150, and 160 to the conductive interconnects 170. For example, surfaces of the contacts 140, 150, and 160 and surfaces of the conductive interconnects 170 are activated through various processes, such as plasma treatment or chemical modification. A high precision alignment system is used to align the contacts 140, 150, and 160, and the conductive interconnects 170. Once aligned, the surfaces of the contacts 140, 150, and 160 are brought into contact with the surfaces of the conductive interconnects 170 under controlled conditions, such as pressure, temperature, and sometimes electrical or ultrasonic assistance. After bonding, annealing may be performed to improve bond strength and stability of the interface.

Stage 4 illustrates a state after the carrier substrate 408 is removed. The carrier substrate 408 can be removed using mechanical delamination, etching processes, laser ablation operations, thermal release, other targeted carrier substrate removal operations, or combinations thereof. Formation of a device 650 (e.g., a stacked IC device) is complete after stage 4 of FIG. 6. However, in some implementations, the device 650 can be used to form the device 100 of FIG. 1.

Stage 5 illustrates a state after the device 650 is positioned relative to the substrate 102. The substrate 102 includes conductive interconnects 192 on or at a first side of the substrate 102 that are electrically connected to metal layers 194 of the substrate 102. Contacts 190 are formed on the conductive interconnects 192.

Stage 6 illustrates a state after the BEOL layers 184 on or at the second side 174 of the RF interposer chiplet 112 of the device 650 are aligned and bonded with the contacts 190. For example, heating/reflowing can be applied to bond the BEOL layers 184 of the RF interposer chiplet 112 via the contacts 190 and the conductive interconnects 192 to the metal layers 194 of the substrate 102 to form the device 100 of FIG. 1.

As another example, the device 650 with BEOL layers 184 of the second side 174 bonded with the conductive interconnects 170 can be disposed on the substrate 102 and heating/reflowing can be applied to bond the contacts 180 of the RF interposer chiplet 112 via contacts 190 and conductive interconnects 192 to the substrate 102 to form the device 500 of FIG. 5.

FIG. 7 (which is continued across multiple pages) illustrates an exemplary sequence for providing or fabricating a stacked IC device (e.g., the device 500) including a multi-chip package, as described with reference to FIG. 5. It should be noted that the sequence of FIG. 7 may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 7.

Stage 1 of FIG. 7 illustrates at least a portion of the reconstituted wafer 352. In a particular aspect, Stage 1 illustrates a state after dicing of the reconstituted wafer 352 into multiple portions. The portion of the reconstituted wafer 352 includes a package 114 formed on the carrier substrate 408. The package 114 includes an EMI shield 106 between a chiplet 120A and a chiplet 120B. The chiplet 120A, the EMI shield 106, and the chiplet 120B are at least partially encapsulated in the mold compound 104. In a particular aspect, temporary bonding is used to bond the chiplets 120 and the EMI shield 106 to the carrier substrate 408. In some embodiments, redistribution layers (e.g., the RDL 344 of FIG. 3) are formed on the reconstituted wafer, in which case the contacts 140, 150, 160 are contacts of the redistribution layers.

Stage 2 illustrates a state after the portion of the reconstituted wafer 352 is flipped vertically and positioned relative to a RF interposer chiplet 112. The RF interposer chiplet 112 includes the BEOL layers 184 on or at the second side 174 of the RF interposer chiplet 112 with conductive interconnects 170 formed (e.g., deposited) on the BEOL layers 184. In a particular aspect, the portion of the reconstituted wafer 352 is positioned to align the contacts 140, 150, and 160 of the package 114 with the conductive interconnects 170 on the RF interposer chiplet 112. For example, a contact 140 of the chiplet 120A is aligned with a conductive interconnect 170A, a contact 150 of the EMI shield 106 is aligned with a conductive interconnect 170B, a contact 160 of the chiplet 120B is aligned with a conductive interconnect 170.

Stage 3 illustrates a state after the contacts 140, 150, and 160 of the portion of the reconstituted wafer 352 are aligned and bonded with the conductive interconnects 170 on the RF interposer chiplet 112. In some implementations, hybrid bonding is used to bond the contacts 140, 150, and 160 to the conductive interconnects 170.

Stage 4 illustrates a state after the carrier substrate 408 is removed. Formation of a device 750 (e.g., a stacked IC device) is complete after stage 4 of FIG. 7. However, in some implementations, the device 750 can be used to form the device 500 of FIG. 1.

Stage 5 illustrates a state after the device 750 is positioned relative to the substrate 102. The substrate 102 includes conductive interconnects 192 on or at a first side of the substrate 102. In the example of FIG. 7, the metal layers 194 are absent from the substrate 102. Contacts 190 are formed on the conductive interconnects 192.

Stage 6 illustrates a state after the contacts 180 on or at the first side 172 of the RF interposer chiplet 112 of the device 650 are aligned and bonded with the contacts 190. For example, heating/reflowing can be applied to bond the contacts 180 of the RF interposer chiplet 112 via the contacts 190 and the conductive interconnects 192 to the substrate 102 to form the device 500 of FIG. 5.

### Exemplary Flow Diagram of a Method for Fabricating an Integrated Circuit Device Comprising a Multi-Chip Package

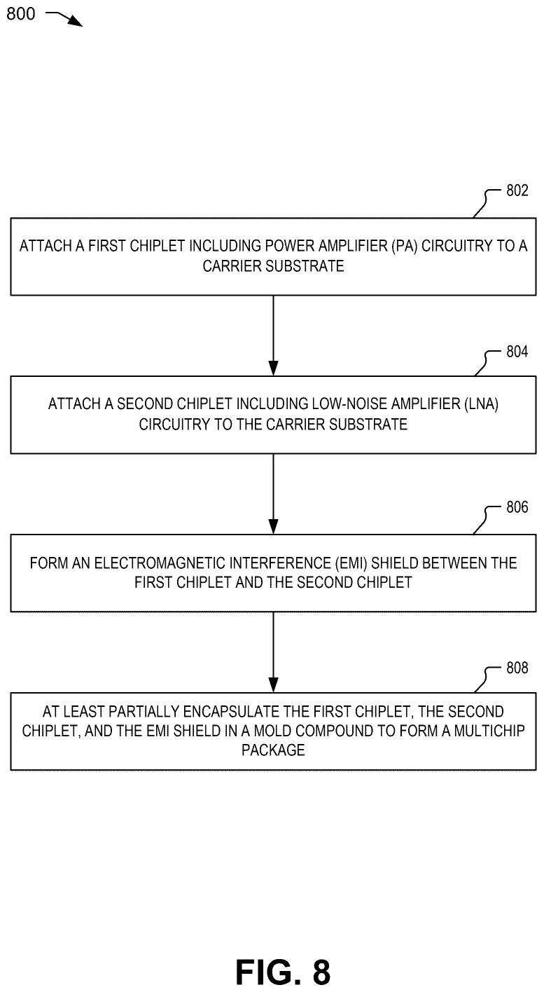

In some implementations, fabricating an IC device includes several processes. FIG. 8 illustrates an exemplary flow diagram of a method 800 for providing or fabricating a stacked IC device including a multi-chip package. In some implementations, the method 800 of FIG. 8 may be used to provide or fabricate any of the stacked IC devices 100, 500, 650, or 750 of FIGS. 1-7.

It should be noted that the method 800 of FIG. 8 may combine one or more processes in order to simplify and/or clarify the method for providing or fabricating an integrated circuit device. In some implementations, the order of the processes may be changed or modified.

The method 800 includes, at block 802, attaching a first chiplet including power amplifier (PA) circuitry to a carrier substrate. For example, the chiplet 120A including the PA circuitry 108 is attached to a carrier substrate 408 as part of the package 114.

The method 800 includes, at block 804, attaching a second chiplet including low-noise amplifier (LNA) circuitry to the carrier substrate. For example, the chiplet 120B including the LNA circuitry 110 is attached to the carrier substrate 408 as part of the package 114.

The method 800 includes, at block 806, forming an electromagnetic interference (EMI) shield between the first chiplet and the second chiplet. For example, the EMI shield 106 is attached to the carrier substrate 408 positioned to be between the chiplet 120A and the chiplet 120B. To illustrate, the EMI shield 106 can be attached to the carrier substrate 408 using a temporary bonding operation.

The method 800 includes, at block 808, at least partially encapsulating the first chiplet, the second chiplet, and the EMI shield in a mold compound to form a multichip package. For example, the chiplet 120A, the chiplet 120B, and the EMI shield 106 are at least partially encapsulated in the mold compound 104 to form a package 114 (e.g., a multi-chip package).

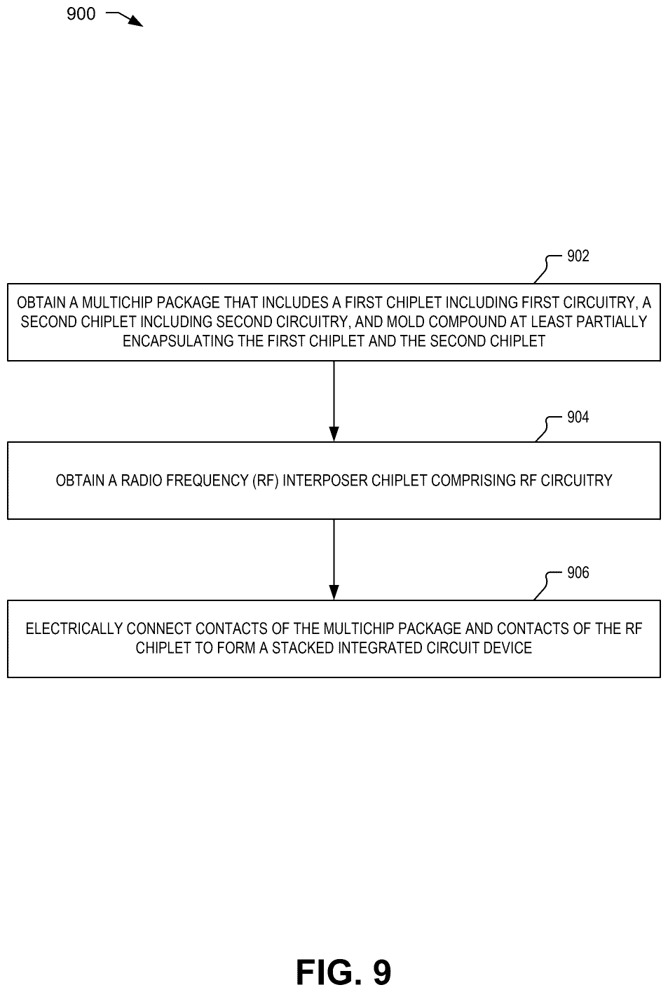

FIG. 9 illustrates an exemplary flow diagram of a method 900 for providing or fabricating a stacked IC device including a multi-chip package. In some implementations, the method 900 of FIG. 9 may be used to provide or fabricate any of the stacked IC devices 100, 500, 650, or 750 of FIGS. 1-7.

It should be noted that the method 900 of FIG. 9 may combine one or more processes in order to simplify and/or clarify the method for providing or fabricating an integrated circuit device. In some implementations, the order of the processes may be changed or modified.

The method 900 includes, at block 902, obtaining a multichip package that includes a first chiplet including first circuitry, a second chiplet including second circuitry, and mold compound at least partially encapsulating the first chiplet and the second chiplet. For example, a package 114 is obtained by dicing a reconstituted wafer 352. The package 114 includes a chiplet 120A including first circuitry (e.g., PA circuitry 108) and a chiplet 120B including second circuitry (e.g., LNA circuitry 110), as described with reference to FIG. 3.

The method 900 includes, at block 904, obtaining a radio frequency (RF) interposer chiplet comprising RF circuitry. For example, a RF interposer chiplet 112 is obtained. The RF interposer chiplet 112 includes RF circuitry, such as a receiver, a transmitter, or both.

The method 900 includes, at block 906, electrically connecting contacts of the multichip package and contacts of the RF interposer chiplet to form a stacked integrated circuit device. For example, the contacts 140, 150, and 160 of the package 114 are electrically connected to the contacts 180 of the RF interposer chiplet 112, as described with reference to FIGS. 1 and 6. As another example, the contacts 140, 150, and 160 of the package 114 are electrically connected to the BEOL layers 184 of the RF interposer chiplet 112, as described with reference to FIGS. 5 and 7.

### Exemplary Electronic Devices

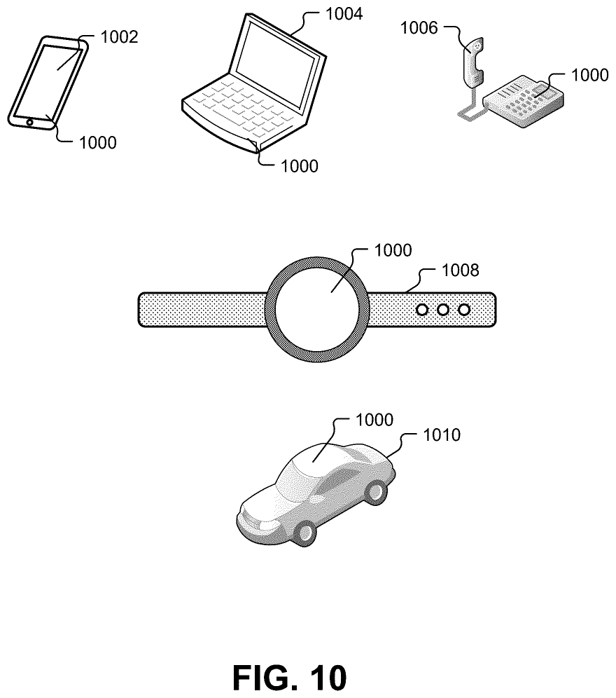

FIG. 10 illustrates various electronic devices that may include or be integrated with any of the devices 100, 500, 650, or 750. For example, a mobile phone device 1002, a laptop computer device 1004, a fixed location terminal device 1006, a wearable device 1008, or a vehicle 1010 (e.g., an automobile or an aerial device) may include a device 1000. The device 1000 can include, for example, any of the devices 100, 500, or 650 described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-10 may be rearranged and/or combined into a single component, process, feature or function or embodied in several components, processes, or functions. Additional elements, components, processes, and/or functions may also be added without departing from the disclosure. It should also be noted FIGS. 1-10 and its corresponding description in the present disclosure is not limited to dies and/or ICs. In some implementations, FIGS. 1-10 and its corresponding description may be used to manufacture, create, provide, and/or produce devices and/or integrated devices. In some implementations, a device may include a die, an integrated device, a multi-chip package, an integrated passive device (IPD), a die package, an integrated circuit (IC) device, a device package, an integrated circuit (IC) package, a wafer, a semiconductor device, and/or a package-on-package (POP) device.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a multi-chip package includes a first chiplet including power amplifier (PA) circuitry; a second chiplet including low-noise amplifier (LNA) circuitry; an electromagnetic interference (EMI) shield between the first chiplet and the second chiplet; and mold compound at least partially encapsulating the first chiplet, the second chiplet, and the EMI shield.

Example 2 includes the multi-chip package of Example 1, further comprising a filter chiplet.

Example 3 includes the multi-chip package of Example 1 or Example 2, further comprising a switch chiplet.

Example 4 includes the multi-chip package of any of Examples 1 to 3, wherein the EMI shield includes a plurality of conductive structures.

Example 5 includes the multi-chip package of any of Examples 1 to 3, wherein the EMI shield is a single conductive structure.

Example 6 includes the multi-chip package of any of Examples 1 to 5, and further includes contacts configured to electrically connect the PA circuitry to a transmitter chiplet.

Example 7 includes the multi-chip package of any of Examples 1 to 6, and further includes contacts configured to electrically connect the LNA circuitry to a receiver chiplet.

Example 8 includes the multi-chip package of any of Examples 1 to 7, and further includes one or more redistribution layers coupled to the mold compound and electrically connected to the first chiplet, the EMI shield, and the second chiplet.

Example 9 includes the multi-chip package of any of Examples 1 to 8, wherein the first chiplet includes a first substrate of a first substrate material that is distinct from a second substrate material of a second substrate of the second chiplet.

Example 10 includes the multi-chip package of Example 9, wherein the first substrate material includes at least one of gallium arsenide (GaAs) or indium phosphide (InP), and the second substrate material includes silicon (Si).

According to Example 11, a packaged integrated circuit device includes a first chiplet including power amplifier (PA) circuitry; a second chiplet including low-noise amplifier (LNA) circuitry; and a third chiplet including: radio frequency (RF) circuitry; first contacts on a first surface, wherein a first subset of the first contacts are electrically connected to the first chiplet and a second subset of the first contacts are electrically connected to the second chiplet; second contacts on a second surface, the second contacts configured to electrically connect to off package components; and conductors electrically connecting one or more of the first contacts to one or more of the second contacts.

Example 12 includes the packaged integrated circuit device of Example 11, further comprising a filter chiplet.

Example 13 includes the packaged integrated circuit device of Example 11 or Example 12, further comprising a switch chiplet.

Example 14 includes the packaged integrated circuit device of any of Examples 11 to 13, and further includes an electromagnetic interference (EMI) shield between the first chiplet and the second chiplet.

Example 15 includes the packaged integrated circuit device of Example 14, wherein the EMI shield includes a plurality of conductive structures.

Example 16 includes the packaged integrated circuit device of Example 14, wherein the EMI shield is a single conductive structure.

Example 17 includes the packaged integrated circuit device of any of Examples 11 to 16, wherein one or more of the first subset of the first contacts electrically connect the PA circuitry to the RF circuitry.

Example 18 includes the packaged integrated circuit device of any of Examples 11 to 17, wherein one or more of the second subset of the first contacts electrically connect the LNA circuitry to the RF circuitry.

Example 19 includes the packaged integrated circuit device of any of Examples 11 to 18, where the first chiplet, the second chiplet, and the third chiplet are at least partially encapsulated in a mold compound.

Example 20 includes the packaged integrated circuit device of any of Examples 11 to 19, wherein the first chiplet includes a first substrate of a first substrate material that is distinct from a second substrate material of a second substrate of the second chiplet.

Example 21 includes the packaged integrated circuit device of Example 20, wherein the first substrate material includes gallium arsenide (GaAs) or indium phosphide (InP), and the second substrate material includes silicon (Si).

According to Example 22, a stacked integrated circuit device includes a multichip package stacked with a radio frequency (RF) interposer chiplet, the multichip package includes a first chiplet including first circuitry; a second chiplet including second circuitry; and mold compound at least partially encapsulating the first chiplet and the second chiplet; and the RF interposer chiplet includes RF circuitry; and first contacts, on a first surface, electrically connected to the first chiplet and the second chiplet of the multichip package.

Example 23 includes the stacked integrated circuit device of Example 22, wherein the multichip package includes an electromagnetic interference (EMI) shield between the first chiplet and the second chiplet.

Example 24 includes the stacked integrated circuit device of Example 22 or Example 23, wherein the RF interposer chiplet includes: second contacts on a second surface, the second contacts configured to electrically connect to off package components; and conductors electrically connecting one or more of the first contacts to one or more of the second contacts.

According to Example 25, a method of fabrication includes attaching a first chiplet including power amplifier (PA) circuitry to a carrier substrate; attaching a second chiplet including low-noise amplifier (LNA) circuitry to the carrier substrate; forming an electromagnetic interference (EMI) shield between the first chiplet and the second chiplet; and at least partially encapsulating the first chiplet, the second chiplet, and the EMI shield in a mold compound to form a multichip package.

Example 26 includes the method of Example 25, further comprising attaching a plurality of chiplets to the carrier substrate to form a reconstituted wafer.

Example 27 includes the method of Example 25 or Example 26, wherein the plurality of chiplets include multiple PA chiplets, multiple LNA chiplets, or a combination thereof.

Example 28 includes the method of any of Examples 25 to 27, further includes removing the carrier substrate; and after removing the carrier substrate, separating the multichip package from other portions of a reconstituted wafer.

Example 29 includes the method of any of Examples 25 to 28, wherein forming the EMI shield includes forming multiple conductive structures between the first chiplet and the second chiplet.

Example 30 includes the method of any of Examples 25 to 29, and further includes attaching the multichip package to a third chiplet, wherein the third chiplet includes radio frequency (RF) circuitry.

Example 31 includes the method of any of Examples 25 to 30, wherein forming the EMI shield includes forming a single conductive structure between the first chiplet and the second chiplet.

According to Example 32, a method of fabrication of an integrated device includes obtaining a multichip package that includes a first chiplet including first circuitry; a second chiplet including second circuitry; and mold compound at least partially encapsulating the first chiplet and the second chiplet; obtaining a radio frequency (RF) interposer chiplet comprising RF circuitry; and electrically connecting contacts of the multichip package and contacts of the RF interposer chiplet to form a stacked integrated circuit device.

Example 33 includes the method of Example 32, wherein the first circuitry includes power amplifier (PA) circuitry, and the second circuitry includes low-noise amplifier (LNA) circuitry.

Example 34 includes the method of Example 32 or Example 33, wherein the embedded multichip package includes an electromagnetic interference (EMI) shield between the first chiplet and the second chiplet.

Example 35 includes the method of any of Examples 32 to 34, wherein the RF interposer chiplet includes conductors electrically connecting the contacts of the RF interposer chiplet on a first surface to second contacts of the RF interposer chiplet on a second surface.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A multi-chip package comprising:
a first chiplet including power amplifier (PA) circuitry;
a second chiplet including low-noise amplifier (LNA) circuitry;
an electromagnetic interference (EMI) shield between the first chiplet and the second chiplet; and
a mold compound at least partially encapsulating the first chiplet, the second chiplet, and the EMI shield.

2. The multi-chip package of claim 1, further comprising a filter chiplet.

3. The multi-chip package of claim 1, further comprising a switch chiplet.

4. The multi-chip package of claim 1, wherein the EMI shield includes a plurality of conductive structures.

5. The multi-chip package of claim 1, wherein the EMI shield is a single conductive structure.

6. The multi-chip package of claim 1, further comprising contacts configured to electrically connect the PA circuitry to a transmitter chiplet.

7. The multi-chip package of claim 1, further comprising contacts configured to electrically connect the LNA circuitry to a receiver chiplet.

8. The multi-chip package of claim 1, further comprising one or more redistribution layers coupled to the mold compound and electrically connected to the first chiplet, the EMI shield, and the second chiplet.

9. The multi-chip package of claim 1, wherein the first chiplet includes a first substrate of a first substrate material that is distinct from a second substrate material of a second substrate of the second chiplet.

10. The multi-chip package of claim 9, wherein the first substrate material includes at least one of gallium arsenide (GaAs) or indium phosphide (InP), and the second substrate material includes silicon (Si).

11. A packaged integrated circuit device comprising:
a first chiplet including power amplifier (PA) circuitry;
a second chiplet including low-noise amplifier (LNA) circuitry; and
a third chiplet including:
radio frequency (RF) circuitry;
first contacts on a first surface, wherein a first subset of the first contacts are electrically connected to the first chiplet and a second subset of the first contacts are electrically connected to the second chiplet;
second contacts on a second surface, the second contacts configured to electrically connect to off package components; and
conductors electrically connecting one or more of the first contacts to one or more of the second contacts.

12. The packaged integrated circuit device of claim 11, further comprising a filter chiplet.

13. The packaged integrated circuit device of claim 11, further comprising a switch chiplet.

14. The packaged integrated circuit device of claim 11, further comprising an electromagnetic interference (EMI) shield between the first chiplet and the second chiplet.

15. The packaged integrated circuit device of claim 14, wherein the EMI shield includes a plurality of conductive structures.

16. The packaged integrated circuit device of claim 14, wherein the EMI shield is a single conductive structure.

17. The packaged integrated circuit device of claim 11, wherein one or more of the first subset of the first contacts electrically connect the PA circuitry to the RF circuitry.

18. The packaged integrated circuit device of claim 11, wherein one or more of the second subset of the first contacts electrically connect the LNA circuitry to the RF circuitry.

19. The packaged integrated circuit device of claim 11, where the first chiplet, the second chiplet, and the third chiplet are at least partially encapsulated in a mold compound.

20. The packaged integrated circuit device of claim 11, wherein the first chiplet includes a first substrate of a first substrate material that is distinct from a second substrate material of a second substrate of the second chiplet.

21. The packaged integrated circuit device of claim 20, wherein the first substrate material includes at least one of gallium arsenide (GaAs) or indium phosphide (InP), and the second substrate material includes silicon (Si).

22. A stacked integrated circuit device comprising:
a multichip package stacked with a radio frequency (RF) interposer chiplet, the multichip package comprising:
a first chiplet including first circuitry;
a second chiplet including second circuitry; and
a mold compound at least partially encapsulating the first chiplet and the second chiplet; and
the RF interposer chiplet comprising:
RF circuitry; and
first contacts, on a first surface, electrically connected to the first chiplet and the second chiplet of the multichip package.

23. The stacked integrated circuit device of claim 22, wherein the multichip package includes an electromagnetic interference (EMI) shield between the first chiplet and the second chiplet.

24. The stacked integrated circuit device of claim 22, wherein the RF interposer chiplet includes:
second contacts on a second surface, the second contacts configured to electrically connect to off package components; and
conductors electrically connecting one or more of the first contacts to one or more of the second contacts.

25. A method of fabrication, the method comprising:
attaching a first chiplet including power amplifier (PA) circuitry to a carrier substrate;
attaching a second chiplet including low-noise amplifier (LNA) circuitry to the carrier substrate;
forming an electromagnetic interference (EMI) shield between the first chiplet and the second chiplet; and
at least partially encapsulating the first chiplet, the second chiplet, and the EMI shield in a mold compound to form a multichip package.

26. The method of claim 25, further comprising attaching a plurality of chiplets to the carrier substrate to form a reconstituted wafer.

27. The method of claim 26, wherein the plurality of chiplets include multiple PA chiplets, multiple LNA chiplets, or a combination thereof.

28. The method of claim 25, further comprising:
removing the carrier substrate; and
after removing the carrier substrate, separating the multichip package from other portions of a reconstituted wafer.

29. The method of claim 25, wherein forming the EMI shield includes forming multiple conductive structures between the first chiplet and the second chiplet.

30. The method of claim 25, further comprising attaching the multichip package to a third chiplet, wherein the third chiplet includes radio frequency (RF) circuitry.
